(19) United States
(12) Patent Application Publication
(10) Pub. No.: US 2014/0182815 A1
(43) Pub. Date: Jul. 3, 2014

(54) HOLDER FOR PORTABLE ELECTRONIC DEVICE

(71) Applicant: FIH (HONG KONG) LIMITED, Kowloon (HK)

(72) Inventors: KUANG-HSIA SHIH, New Taipei (TW); JHIH-JIE JIANG, New Taipei (TW)

(73) Assignee: FIH (HONG KONG) LIMITED, Kowloon (HK)

(21) Appl. No.: 14/014,683

(22) Filed: Aug. 30, 2013

(30) Foreign Application Priority Data
Dec. 28, 2012 (TW) 101151284

(51) Int. Cl. H05K 7/20; B62J 11/00

(52) U.S. Cl. CPC H05K 7/20409; B62J 11/00
USPC 165/80.3; 224/420

(57) ABSTRACT

A holder for a portable electronic device includes a seat, a receiving member, a thermal pad, and a heat dissipation sink. The receiving member is connected to the seat, and defines a receiving space configured to receive the portable electronic device. The thermal pad is received in the receiving space, and the heat dissipation sink is connected to the receiving member. When the portable electronic device is received in the receiving space, the thermal pad contacts the portable electronic device and transmits heat generated by the portable electronic device to the receiving member, so that the heat is dissipated by the heat dissipation sink.

### BACKGROUND

1. Technical Field

The exemplary disclosure generally relates to holders, and particularly to a holder for holding a portable electronic device (e.g., mobile phones) on a bicycle.

2. Description of Related Art

To use portable electronic devices, such as a mobile phone, for navigation while riding a bicycle, the mobile phone needs to be mounted on the bicycle. Typically, a holder is needed to support and protect the mobile phone. However, the holder is unable to effectively dissipate heat generated by the mobile phone.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

FIG. 1 is an exploded view of an exemplary embodiment of a holder for a mobile phone.

FIG. 2 is similar to FIG. 1, but shown from another aspect.

FIG. 3 is an assembled view of the holder of FIG. 1.

FIG. 4 is similar to FIG. 3, but shows the holder holding a portable electronic device.

### DETAILED DESCRIPTION

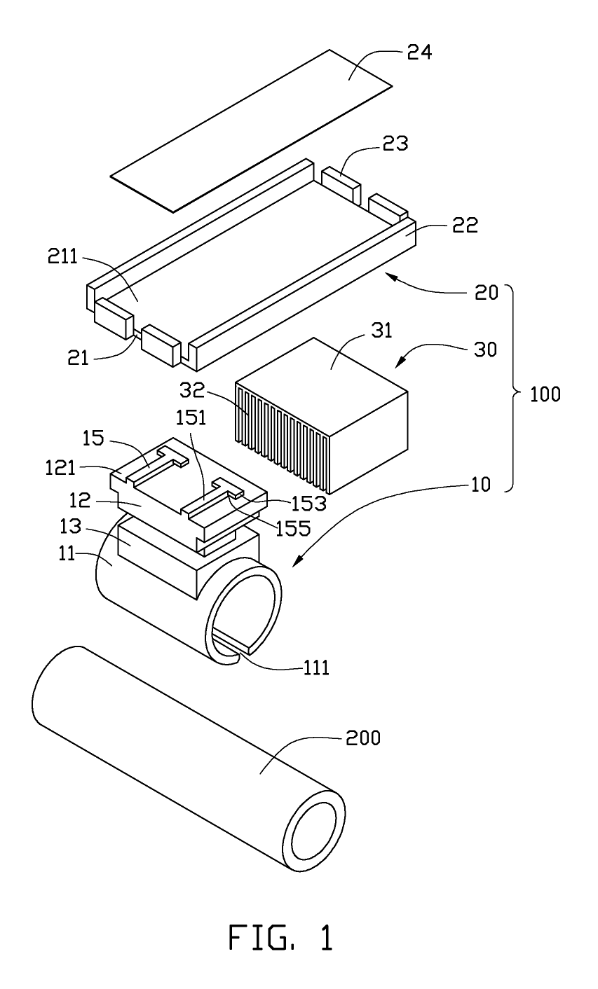

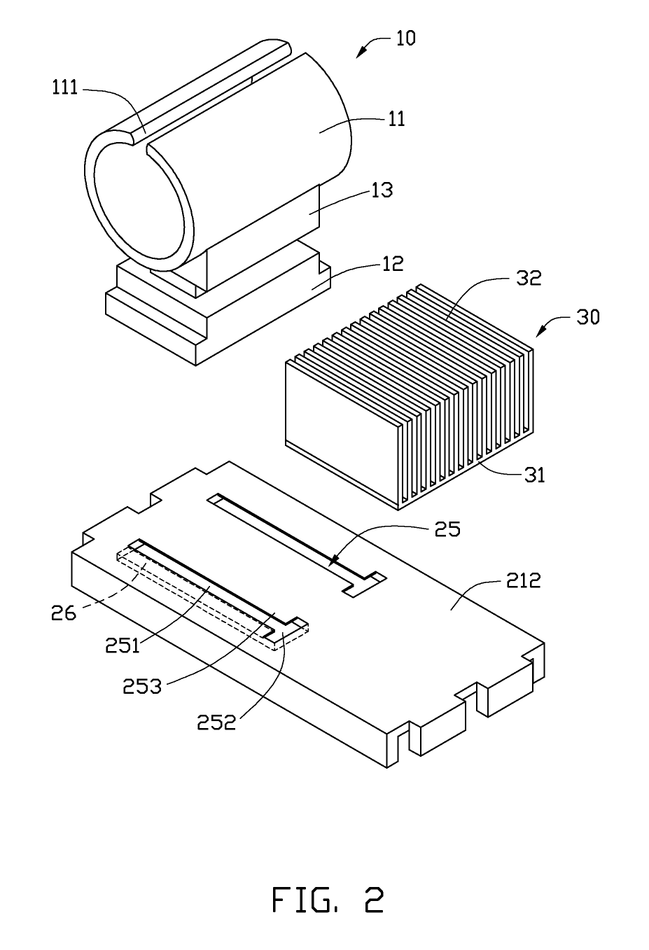

FIGS. 1 and 2 show an exemplary embodiment of a holder 100 used for holding a portable electronic device on a handle bar 200 of a bicycle (not shown). The portable electronic device can be a mobile phone, an MP4 player, or a personal digital assistant, for example. The holder 100 includes a seat 10, a receiving member 20, a thermal pad 24, and a heat dissipation sink 30.

The seat 10 is made of plastic material and includes a mounting portion 11, a latching portion 12, and a connecting portion 13 integrally formed together. The mounting portion 11 is configured for being held on the handle bar 200. In this exemplary embodiment, the mounting portion 11 is a sleeve, and defines a slit 111. The mounting portion 11 can be stretched along the slit 111 for allowing the handle bar 200 to be received in the mounting portion 11. The latching portion 12 is configured for latching the receiving member 20 on the seat 10. The connecting portion 13 connects the mounting portion 11 to the latching portion 12. In this exemplary embodiment, the latching portion 12 is a stepped plate, and has a planar surface 121 opposite to the mounting portion 11. The planar surface 121 has two spaced latching blocks 15. In this exemplary embodiment, each latching block 15 is substantially

T-shaped, and includes a first beam 151 and a second beam 153 perpendicularly connected to one end of the first beam 151. The first beam 151 is formed on the planar surface 121. A thickness of the second beam 153 is thinner than a thickness of the first beam 151. One side of the second beam 153 is coplanar with the first beam 151, and opposite two ends of the second beam 153 are spaced from the planar surface 121 to define two guiding grooves 155.

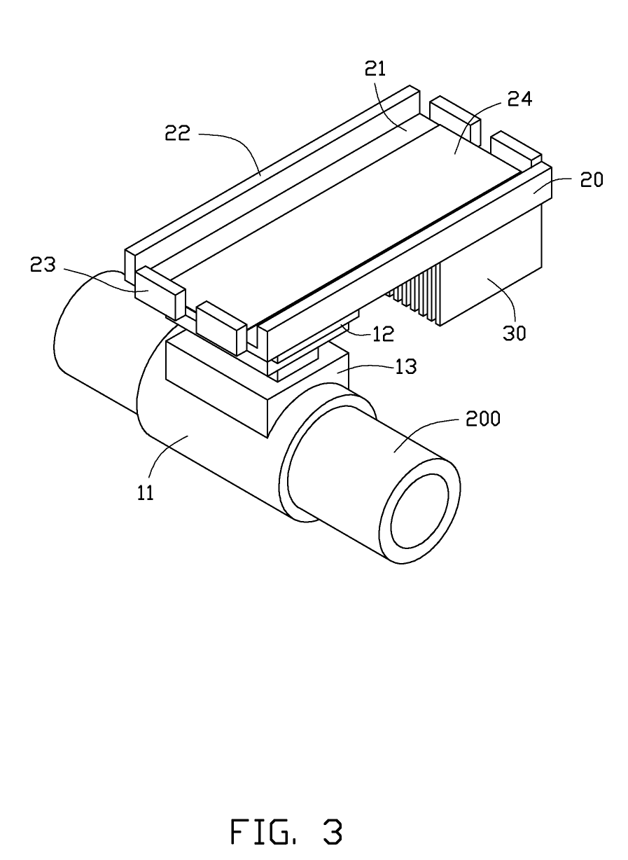

Referring to FIG. 3, the receiving member 20 is made of metal, such as aluminum alloy. The receiving member 20 has a base plate 21, two side portions 22, and two end portions 23. The base plate 21 is substantially rectangular, and includes a first surface 211 and a second surface 212 opposite to the first surface 211. The two side portions 22 extend from opposite sides of the base plate 21, and the two end portions 23 extend from other opposite ends of the base plate 21, thereby defining a receiving space for receiving a portable electronic device. The first surface 211 is located in the receiving space. The second surface 212 of the base plate 21 defines two guiding portions configured for engaging with the latching blocks 15. Each guiding portion includes an opening 25 and a receiving groove 26 below the opening 25. Shapes of the openings 25 correspond to shapes of the latching blocks 15, and have a first part opening 251 and a second part opening 252. Two extending plates 253 are positioned above the receiving groove 26, and are formed at opposite sides of the first part opening 251. When the latching portion 12 is assembled to the receiving member 20, the first beam 151 of each latching block 15 is received in the receiving groove 26 via the first part opening 251. The second beam 152 is received in the receiving groove 26 via the second part opening 252, and the extending plates 253 are received in the guiding grooves 153 to enable the seat 10 to slide relative to the receiving member 20 until the second beam 152 is latched in the receiving groove 26 at a predetermined position.

The thermal pad 24 is attached to the first surface 211 of the base plate 21. The thermal pad 24 is elastic and is made of high thermal conductivity material. A shape of the thermal pad 24 can be changed according to a shape of the portable electronic device. When the portable electronic device is received in the receiving member 20, the thermal pad 24 contacts and elastically abuts against a bottom surface of the portable electronic device. Accordingly, heat produced by the portable electronic device is effectively transmitted to the thermal pad 24. In this exemplary embodiment, the thermal pad 24 is made of composite material, and has a thermal conductivity of about 5 watt/ per meter kelvin.

The heat dissipation sink 30 is mounted on the second surface 212 of the receiving member 20. The heat dissipation sink 30 can be integrally formed with the receiving member or be assembled together. In this exemplary embodiment, a position of the heat dissipation sink 30 on the receiving member 20 corresponds to a battery of the portable electronic device received in the receiving member 20. The heat dissipation sink 30 has a main body 31 and a plurality of fins 32. The main body 31 is integrally formed on the second surface 212 of the receiving member 20. The fins 32 protrude from the main body 31, and are parallel to each other. Heat generated by the portable electronic device is transmitted to the heat dissipation sink 30.

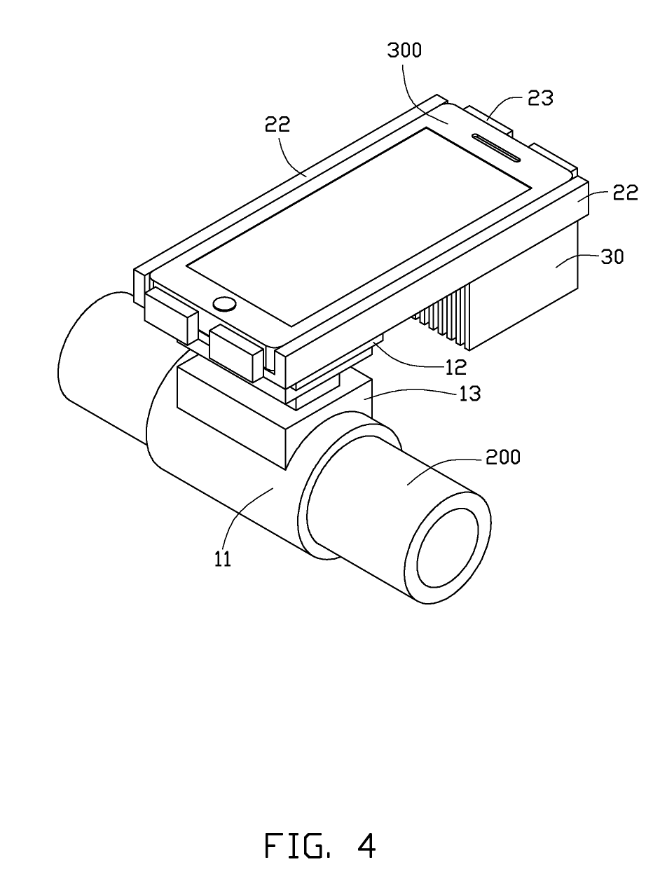

In use, referring to FIG. 4, the thermal pad 24 is received in the receiving space. A portable electronic device 300 is received in the receiving space of the holder 100, and elastically abuts against the thermal pad 24. The mounting portion 11 of the seat 10 is fitted around the handle bar 200 of a bicycle. Thus, the portable electronic device 300 is mounted on the bicycle by the holder 100. The portable electronic device 300 contacts the thermal pad 24. Heat generated by the portable electronic device 300 is transmitted to the heat dissipation sink 30 via the thermal pad 24 and the receiving member 20. Therefore, the portable electronic device supported by the holder 100 has improved heat dissipation efficiency.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A holder for a portable electronic device, the holder comprising:
a seat;
a receiving member connected to the seat, and defining a receiving space for receiving the portable electronic device;
a thermal pad received in the receiving space; and
a heat dissipation sink being connected to the receiving member;
wherein when the portable electronic device is received in the receiving space, the thermal pad contacts with the portable electronic device and transmits heat from the portable electronic device to the receiving member so that the heat is dissipated by the heat dissipation sink.

2. The holder as claimed in claim 1, wherein the seat includes a latching portion, the latching portion has two spaced latching blocks, the receiving member includes two guiding portions engaging with the latching blocks.

3. The holder as claimed in claim 2, wherein each latching block includes a first beam and a second beam perpendicularly connected to one end of the first beam, each guiding portion defines an opening and a receiving groove below the opening, the opening has a first part opening and a second part opening, the first beam of each latching block is received in the receiving groove from the first part opening, the second beam is received in the receiving groove from the second part opening.

4. The holder as claimed in claim 3, wherein two extending plates are positioned above the receiving groove, and formed at opposite sides of the first part opening, a thickness of the second beam is thinner than a thickness of the first beam, two guiding grooves are defined between the second beam and a planar surface of the receiving member, and the extending plates are slidably received in the guiding grooves.

5. The holder as claimed in claim 1, wherein the seat is made of plastic material, and the receiving member and the heat dissipation sink are integrally formed together and are made of metal material.

6. The holder as claimed in claim 1, wherein the seat includes a mounting portion, a latching portion, and a connecting portion integrally formed together, the mounting portion is configured for being held on the handle bar, the connecting portion connects the mounting portion to the latching portion.

7. The holder as claimed in claim 6, wherein the mounting portion is a sleeve and defines a slit, the mounting portion is stretched along the slit configured for allowing the handle bar to be received in the mounting portion.

8. The holder as claimed in claim 6, wherein the latching portion is a stepped plate, and has a planar surface opposite to the mounting portion, the planar surface has two spaced latching blocks, the receiving member includes two guiding portions engaging with the latching blocks.

9. A holder for a portable electronic device, comprising:
a receiving member defining a receiving space to receive the portable electronic device;
a guiding heat member; and
a heat dissipation sink assembled to the receiving member, wherein when the portable electronic device is received in the receiving space, the guiding heat member is positioned between the receiving member and the portable electronic device and transmits heat from the portable electronic device to the guiding heat member and the receiving member to dissipate the heat.

10. The holder as claimed in claim 9, further comprising a seat, wherein the seat includes a latching portion, the latching portion has two spaced latching blocks, the receiving member includes two guiding portions engaging with the latching blocks.

11. The holder as claimed in claim 10, wherein each latching block includes a first beam and a second beam perpendicularly connected to one end of the first beam, each guiding portion defines an opening and a receiving groove below the opening, the opening has a first part opening and a second part opening, the first beam of each latching block is received in the receiving groove from the first part opening, the second beam is received in the receiving groove from the second part opening.

12. The holder as claimed in claim 11, wherein two extending plates are positioned above the receiving groove, and formed at opposite sides of the first part opening, a thickness of the second beam is thinner than a thickness of the first beam, two guiding grooves are defined between the second beam and a planar surface of the receiving member, and the extending plates are slidably received in the guiding grooves.

13. The holder as claimed in claim 10, wherein the seat is made of plastic material, and the receiving member and the heat dissipation sink are integrally formed together and are made of metal material.

14. The holder as claimed in claim 10, wherein the seat includes a mounting portion, a latching portion, and a connecting portion integrally formed together, the mounting portion is configured for being held on the handle bar, the connecting portion connects the mounting portion to the latching portion.

15. The holder as claimed in claim 14, wherein the mounting portion is a sleeve and defines a slit, the mounting portion is stretched along the slit for allowing the handle bar to be received in the mounting portion.

16. The holder as claimed in claim 14, wherein the latching portion is a stepped plate and has a planar surface opposite to the mounting portion, the planar surface has two spaced latching blocks, the receiving member includes two guiding portions engaging with the latching blocks.
